(19) United States
(12) Patent Application Publication
(10) Pub. No.: US 2008/0191797 A1
(43) Pub. Date: Aug. 14, 2008

(54) HIGH PASS FILTER CIRCUIT WITH LOW CORNER FREQUENCY

(75) Inventors: Chinq-shiun Chiu, Hsinchu City (TW); Jiqing Cui, Singapore (SG)

Correspondence Address: MADSON & AUSTIN, 15 WEST SOUTH TEMPLE, SUITE 900, SALT LAKE CITY, UT, 84101, US

(73) Assignee: MediaTek Inc., Hsin-Chu (TW)

(21) Appl. No.: 11/672,717

(22) Filed: Feb. 8, 2007

(51) Int. Cl. H03B 1/00; H04B 1/10

(52) U.S. Cl. 327/559; 455/307

(57) ABSTRACT

A high pass filter circuit having a signal input terminal and a signal output terminal. The high pass filter circuit is provided with a voltage source, first and second inverters, and a capacitor. The voltage source provides a DC bias voltage. The first inverter couples to the voltage source to invert the DC bias voltage. The second inverter couples to the first inverter and a signal output terminal respectively. The second inverter inverts the DC bias voltage inverted by the first inverter to provide the DC bias voltage to the signal output terminal. The second inverter also provides large impedance at the signal output terminal. The capacitor is coupled between the signal input terminal and the signal output terminal to provide a low corner frequency in cooperation with the second inverter. The circuit further comprises an operational amplifier. The voltage source provides the DC bias voltage through the operational amplifier to avoid the total impedance at the output terminal that is decreased by the voltage source.

### FIELD OF THE INVENTION

The present invention generally relates to a high pass filter circuit, more particularly, to a high pass filter circuit having a low corner frequency and providing accurate biasing voltage.

### BACKGROUND OF THE INVENTION

Direct conversion technique is going to be employed widely nowadays in radio frequency (RF) applications. The influence of the DC offset cancellation is a significant topic for a direct conversion receiver (DCR). For example, an AC-coupled circuit is typically used to implement DC offset cancellation to filter out the DC subsequently. In addition, it is necessary to provide a DC bias voltage at this stage to the following module, such as an analog-to-digital converter (ADC).

A typical prior art for voltage biasing scheme is shown in FIG. 1. As disclosed in U.S. Pat. No. 5,760,651, an inductorless voltage biasing circuit is disclosed. An amplifier 10 is coupled with capacitors Cᵢₙ 12 and Cₒᵤₜ 14 between input and output terminals Vᵢₙ and Vₒᵤₜ respectively. A differential-input amplifier 18 is coupled to the amplifier 10 for voltage biasing function. The output point 20 of the differential input amplifier 18 is coupled to the control terminal 16 of the amplifier 10 via a resistor 22. The non-inverted input of the differential input amplifier 18 is connected with a DC voltage source V_{B}. The inverted input of the differential input amplifier 18 is coupled with the control terminal 16 as a negative feedback to decrease the gain of the differential input amplifier 18. However, the impedance of the resistor 22, which is coupled to the control terminal 16 of the amplifier 10, has to be large in such design for insuring this voltage biasing circuit will not load down the amplifier 10 in its operational frequency range. Generally, it means that in a RF receiver, it is employed as a high pass filter having low corner frequency to implement the DC offset cancellation. The resistor with large impedance occupies a large area in integrated circuits now, which significantly increases the cost. More specifically, there is a need to develop a high pass filter circuit having a smaller size element to contribute to a large impedance, and can also provide an accurate biasing voltage at the output point.

### SUMMARY OF THE INVENTION

To solve the foregoing drawbacks in the prior art, it is an objective of the present invention to provide a high pass filter circuit having a low corner frequency and providing accurate bias voltage with low cost

The high pass filter circuit in accordance with the present invention comprises a voltage source, a first inverter, a second inverter, and a capacitor. The voltage source provides a DC bias voltage. The first inverter is coupled to the voltage source to invert the DC bias voltage. The second inverter is coupled to the first inverter and a signal output terminal respectively. The second inverter inverts the DC bias voltage inverted by the first inverter to provide the DC bias voltage to the signal output terminal. The second inverter also provides large impedance. The capacitor couples with second inverter to provide a low corner frequency. Preferably, the voltage source is provided through an operational amplifier for providing the DC bias voltage. Each of the first inverter and second inverter is commonly composed of a p-MOS and a N-MOS connected with each other. Ideally, the first and second inverters match with each other. Preferably, the p-MOS's size of the first inverter matches the p-MOS's size of the second inverter and the n-MOS's size of the first inverter matches the n-MOS's size of the second inverter. The reason for the matching scheme mentioned above is to transfer the DC bias voltage provided by the operational amplifier to the signal output terminal OUT accurately. The DC bias voltage can be calibrated according to the characteristics of the p-MOSs and the n-MOSs. According to the present invention, the transistors of the second inverter, i.e. the p-MOS and n-MOS transistors, provide large impedance. Meaningful to the direct-conversion receiver employed in a wide band system, the high pass filter circuit of the present invention provides a low corner frequency. Furthermore, instead of the resistor with large impedance occupying a large area in an integrated circuit, the high pass filter circuit employs the CMOS transistors having smaller sizes to contribute to large impedance so that it reduces the occupancy area on the chip. It is a significant topic in the circuitry development in modern time.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a prior art simplified voltage biasing circuit employing a resistor in the voltage-mode biasing scheme coupled with an AC-coupled amplifier;

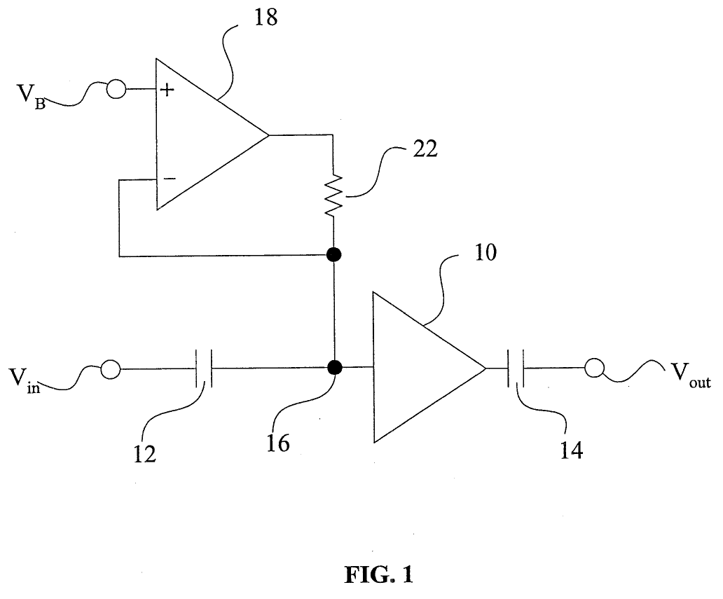

FIG. 2 shows a high pass filter circuit employing CMOS inverters providing large impedance according to a preferred embodiment of the present invention;

FIG. 3 shows a simplified circuit of a direct conversion receiver according to the present invention; and

FIGS. 4a, 4b, 4c, respectively show simulated process corner frequencies at different temperatures according to the preferred embodiment of the present invention.

### DETAILED DESCRIPTION OF THE PREFERRED EMBODIMENTS

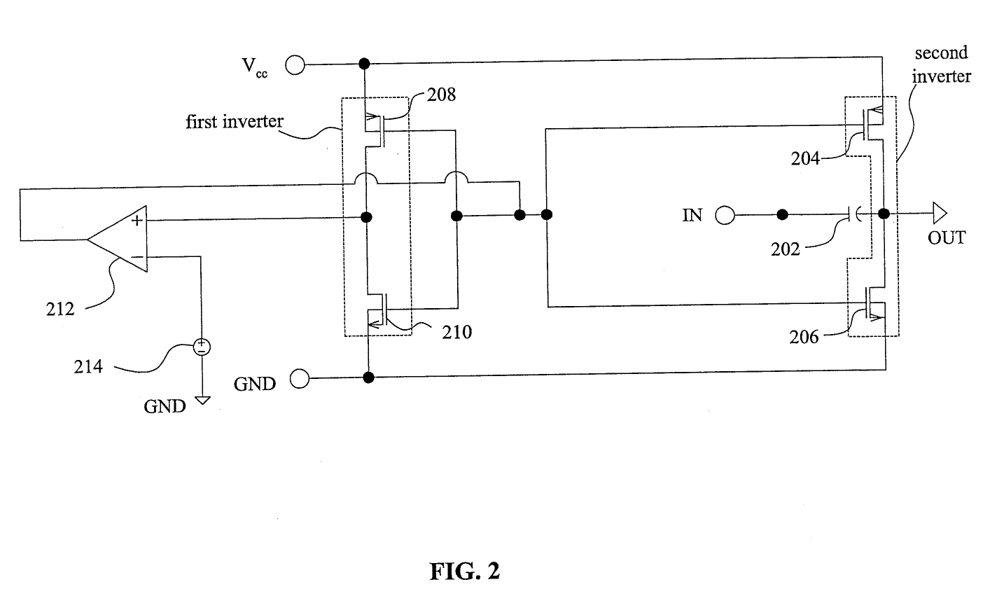

Please refer to FIG. 2, which shows a high pass filter circuit according to a preferred embodiment of the present invention. The high pass filter circuit has a signal input terminal IN and a signal output terminal OUT. In addition, the high pass filter circuit includes a capacitor 202, a first inverter composed of transistors 208, 210, a second inverter composed of transistors 204, 206, a voltage source 214, and an operational amplifier 212. For the DC offset removal, the capacitor 202 is arranged to connect with the second inverter providing a large impedance to apply an AC-coupling to block the DC offset. The transistors in the first and second inverters are CMOS transistors in this preferred embodiment. In this embodiment, the transistors 204, 208 are p-MOS transistors, the transistors 206, 210 are n-MOS transistors. The capacitor 202 is coupled between the signal input terminal IN and the signal output terminal OUT. The drain of the transistor 204 and the drain of the transistor 206 are coupled to the signal output terminal OUT. The sources of the transistor 204 and the transistor 208 are coupled to V_{cc}. The sources of the transistors 206 and the transistor 210 are coupled to ground (GND). The gates of the transistors 204, 206, 208 and 210 are connected together. Meanwhile, the gates of the transistors 204, 206, 208 and 210 are coupled with an output terminal of the operational amplifier 212. The non-inverted input of operational amplifier 212 is coupled with the drain of the transistors 208 and the drain of the transistors 210. The inverted input of the operational amplifier 212 is coupled with the voltage source 214.

The voltage source 214 provides a DC bias voltage. The connection of the operational amplifier 212 forms a negative feedback, so that voltages at the two inputs of the operational amplifier 212 are virtually the same. Thus, the DC bias voltage 214 can be transmitted through the operational amplifier (OP AMP) 212, the first inverter and the second inverter to the output terminal OUT of the high pass filter circuit. With the first inverter, the DC bias voltage is first-inverted. With the second inverter, the DC bias voltage is second inverted. Ideally, the DC bias voltage is inverted back to the original condition after the two inversions, once forward, and once backward. For inverting the DC bias voltage provided by the voltage source 214 to the signal output terminal OUT accurately, the size of p-MOS 208 of the first inverter matches the size of p-MOS 204 of the second inverter; the size of n-MOS 210 of the first inverter matches the n-MOS's 206 size, i.e. the p-MOS 208, n-MOS 210 connection is just as image mapping with the p-MOS 204, n-MOS 206 connection. Furthermore, by using the band gap voltage of the CMOS transistor as the reference voltage to the operational amplifier 212, the bias point can be accurate and the impedance at the signal output terminal OUT is stable. Accordingly, an accurate DC biasing level is provided to the signal output terminal (OUT) point. Meanwhile, the p-MOS 204, n-MOS 206 connection provides large impedance at the signal output terminal OUT after the capacitor 202.

Furthermore, to achieve the large impedance at the signal output terminal OUT after the capacitor 202, it is preferred that the ratio of channel width and the channel length W/L of each of the p-MOSs 204 and 208, n-MOSs 206 and 210 employed in the present invention is as small as possible, i.e. the transistor with long channel length will be preferred.

Moreover, the reason that the operational amplifier 212 is employed to provide the voltage source 214 is that if the voltage source 214 is directly connected to the signal output terminal OUT, the voltage source 214 with tiny impedance will result in a reduced total impedance although the p-MOS 204, n-MOS 206 connection provides a large impedance at the signal output terminal. Providing the voltage source 214 through an operational amplifier 212 can avoid the above concerns.

In addition, the p-MOS transistor 204, n-MOS transistor 206 can be coupled with one or more p-MOS and n-MOS transistors in a cascode manner, respectively, to increase the provided impedance. Certainly, the p-MOS 208 and n-MOS 210 have to couple the same number of p-MOS and n-MOS for matching with the p-MOS 204, n-MOS 206, accordingly.

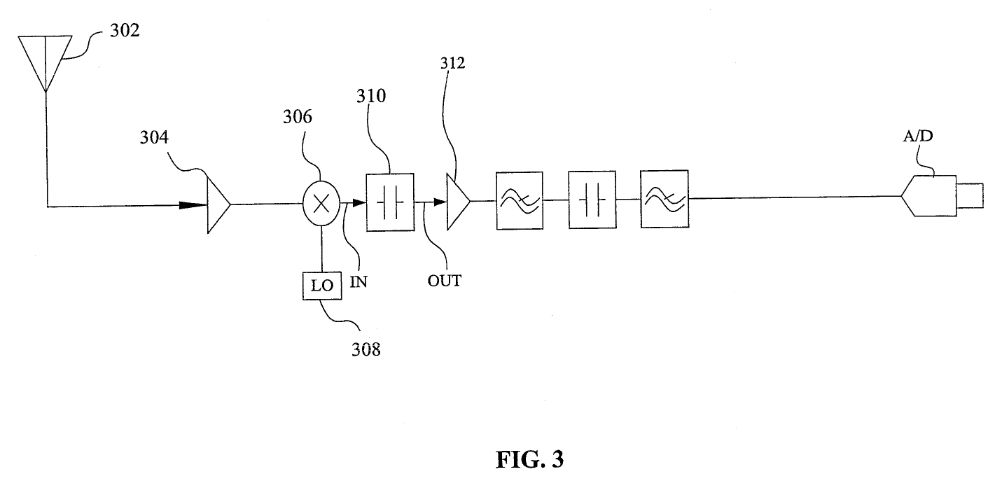

Please refer to FIG. 3, shows a simplified circuit of a direct conversion receiver, which employs the high pass filter circuit according to the preferred embodiment of the present invention. First, the RF signals are received via the signal input terminal 302 and amplified with the Low Noise Amplifier (LNA) 304. Subsequently, the Kr signals are directly down-converted to baseband signals by a mixer 306 with a local oscillation signal provided by a local oscillator (LO) 308. The DC offset often occurs due to the self-mixing phenomenon concerning local oscillator leakage. Meanwhile, there are still other causes to generate the DC offset occurrence. Therefore, a high pass filter 310 is used for DC offset cancellation, a significant topic in any direct conversion receiver for latter signal process. A zero intermediate frequency amplifier 312 coupling to the high pass filter circuit 310 amplifies the signal passing through the high pass filter circuit 310. According to the present invention, the high pass filter having a low corner frequency uses CMOS transistors serving as resistors with large impedance to be coupled with a capacitor to block the DC offset, meanwhile, the virtual size of the circuitry is small. In addition, the CMOS transistors compose the first and second inverters according to the present invention. The two inverters transfer the DC bias voltage from the voltage source to the output of the high pass filter to be fed to the following circuitry. This arrangement can prevent that the low impedance of the voltage source reduces the total impedance at the output of the high pass filter.

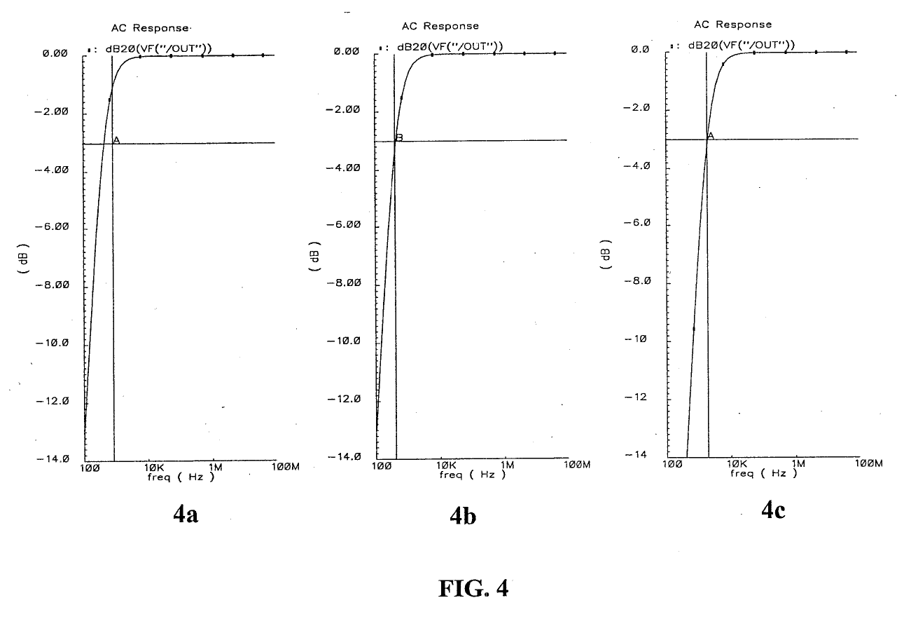

Please refer to FIGS. 4a-4c, the simulated process corner frequency responses at different temperatures according to the preferred embodiment of the present invention are shown. The y-axis represents signals decibel and the x-axis represents frequency. The relationship between frequency and signal decibel at normal temperature is shown in 4a, that at high temperature is shown in 4b, and that at low temperature is shown in 4c. In conclusion, the present invention can maintain good performances at different temperatures, which is also an important factor to DC offset generation.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A high pass filter circuit comprising:
a voltage source for providing a DC bias voltage;
a first inverter to invert the DC bias voltage as a first inverted bias signal;
a second inverter coupling to the first inverter to invert the first inverted bias signal as a second inverted bias signal; and
a capacitor coupling to the second inverter.

2. The high pass filter circuit of claim 1, further comprising an operational amplifier connected with the voltage source, the voltage source provides the DC bias voltage through the operational amplifier.

3. The high pass filter circuit of claim 1, wherein the first inverter and the second inverter match with each other.

4. The high pass filter circuit of claim 1, wherein the first inverter comprises two transistors.

5. The high pass filter circuit of claim 4, wherein the two transistors are a first p-MOS transistor and a first n-MOS transistor.

6. The high pass filter circuit of claim 1, wherein the second inverter comprises two transistors.

7. The high pass filter circuit of claim 6, wherein the two transistors are a second p-MOS transistor and a second n-MOS transistor.

8. The high pass filter circuit of claim 1, wherein the first inverter comprises two transistors, and the second inverted inverter comprises two transistors.

9. The high pass filter circuit of claim 1, wherein the first inverter comprises a first p-MOS transistor and a first n-MOS transistor, and the second inverter comprises a second p-MOS transistor and a second n-MOS transistor.

10. The high pass filter circuit of claim 9, wherein the first and second p-MOS transistors match each other, the first and second n-MOS transistors match each other.

11. The high pass filter circuit of claim 9, wherein the size of the first p-MOS transistor matches the size of the second p-MOS transistor, the size of the first n-MOS transistor matches the size of the second n-MOS transistor.

12. The high pass filter circuit of claim 9, further comprising at least one additional p-MOS transistor coupled to the second p-MOS transistor and at least one additional n-MOS transistor coupled to the second n-MOS transistor, respectively in cascode, for increasing the provided impedance.

13. The high pass filter circuit of claim 12, further comprising at least one additional p-MOS transistor coupled to the first p-MOS transistor and at least one additional n-MOS transistor coupled to the first n-MOS transistor, respectively, in cascode.

14. A direct conversion receiver comprising:
a signal input terminal for receiving a signal;
a low noise amplifier coupled to the signal input terminal, amplifying the signal received from the signal input terminal;
a local oscillator providing a predetermined reference signal;
a mixer coupling to the low noise amplifier and the local oscillator, mixing the signal with the predetermined reference signal to down-convert the signal;
a high pass filter circuit for filtering out a DC component of the down-converted signal from the mixer, the high pass filter circuit comprising:
a voltage source for providing a DC bias voltage;
a first inverter to invert the DC bias voltage as a first inverted bias signal;
a second inverter coupling to the first inverter to invert the first inverted bias signal as a second inverted bias signal; and
a capacitor coupling to the second inverter;
a zero intermediate frequency amplifier, coupled to the high pass filter circuit, the zero intermediate frequency amplifier amplifying the signal from the high pass filter circuit.

15. The direct conversion receiving system of claim 14, wherein the high pass filter circuit further comprises an operational amplifier connected with the voltage source, the voltage source provides the DC bias voltage through the operational amplifier.

16. The direct conversion receiving system of claim 14, wherein the first inverter and the second inverter match each other.

17. The direct conversion receiving system of claim 14, wherein the first inverter comprises two transistors.

18. The direct conversion receiving system of claim 17, wherein the two transistors are a first p-MOS transistor and a first n-MOS transistor.

19. The direct conversion receiving system of claim 14, wherein the second inverter comprises two transistors.

20. The direct conversion receiving system of claim 19, wherein the two transistors are a second p-MOS transistor and a second n-MOS transistor.

21. The direct conversion receiving system of claim 14, wherein the first inverter comprises two transistors, and the second inverted inverter comprises two transistors.

22. The direct conversion receiving system of claim 14, wherein the first inverter comprises a first p-MOS transistor and a first n-MOS transistor, the second inverter comprises a second p-MOS transistor and a second n-MOS transistor.

23. The high pass filter circuit of claim 22, wherein the first and second p-MOS transistors match each other, the first and second n-MOS transistors match each other.

24. The direct conversion receiving system of claim 22, wherein the size of the first p-MOS transistor matches the size of the second p-MOS transistor, the size of the first n-MOS transistor matches the size of the second n-MOS transistor.

25. The high pass filter circuit of claim 22, further comprising at least one additional p-MOS transistor coupled to the second p-MOS transistor and at least one additional n-MOS transistor coupled to the second n-MOS transistor in cascode, respectively, for increasing the provided impedance.

26. The high pass filter circuit of claim 25, further comprising at least one additional p-MOS transistor coupled to the first p-MOS transistor and at least one additional n-MOS transistor coupled to the first n-MOS transistor, respectively, in cascode.
